(19) United States
(12) Patent Application Publication
(10) Pub. No.: US 2025/0391752 A1
(43) Pub. Date: Dec. 25, 2025

(54) PACKAGE STRUCTURE AND PACKAGE METHOD

(71) Applicant: JCET Management Co., LTD., Shanghai (CN)

(72) Inventors: Lihong LIU, Shanghai (CN); Jiongjiong GU, Shanghai (CN); Dayong LEI, Shanghai (CN); Nan WANG, Shanghai (CN)

(73) Assignee: JCET Management Co., LTD., Shanghai (CN)

(21) Appl. No.: 19/219,581

(22) Filed: May 27, 2025

(30) Foreign Application Priority Data
Jun. 24, 2024 (CN) 202410825814.2

(51) Int. Cl. H01L 23/498; H01L 21/60; H01L 23/31; H01L 25/16

(52) U.S. Cl. CPC H01L 23/49811; H01L 21/60; H01L 23/3142; H01L 25/16; H01L 2021/60007

(57) ABSTRACT

A package structure includes a substrate, a chip disposed on the substrate, a plurality of spaced-apart connection pillars disposed on the substrate exposed by the chip, and two ends of an extension direction of the connection pillars are a first end and a second end, respectively, the first end being connected with the substrate, and a base board located above the substrate, and a passive component is formed on a side of the base board facing the chip, the passive component being connected with the second end of the plurality of the connection pillars.

### CROSS-REFERENCE TO RELATED APPLICATIONS

This application claims the benefit of priority to Chinese Application No. 202410825814.2, filed on Jun. 24, 2024, which is hereby incorporated by reference in its entirety.

### TECHNICAL FIELD

The present disclosure relates to the field of semiconductor package, and particularly relates to a package structure and a package method.

### BACKGROUND

Today's highly integrated package technology realizes the compact layout of complex electronic components, and the package process plays a key role in the performance improvement and cost control of electronic components.

During the design and fabrication of 5G RF front-end modules, the integration of active electronic components continues to increase, and the demand for passive components paired with active components grows dramatically, requiring more space to place these passive components. These passive components include, but are not limited to, couplers, various types of filters (e.g., SAW, TF-SAW, BAW, etc.), as well as resistors, capacitors, inductors, and so on.

### SUMMARY

Embodiments of the present disclosure provide a package structure, comprising: a substrate; a chip, located on the base board; a plurality of spaced-apart connection pillars, located on the substrate exposed by the chip, and the two ends in the extension direction of the connection pillars are a first end and a second end, respectively, and the first end is connected with the substrate; a base board, located above the substrate, and one side of the base board facing the chip is formed with a passive component, the passive component is connected with the second end of a plurality of the connection pillars.

Embodiments of the present disclosure further provide a package method, comprising: providing a substrate, the substrate having a chip formed thereon; providing a base board, the base board having a passive component formed thereon; forming a plurality of spaced-apart connection pillars on the passive component, and the two ends in the extension direction of the connection pillars are a first end and a second end, respectively, and the second end of the connection pillars being connected with the passive component; and placing the surface of the base board with the passive component to face the chip, and connecting the first end of the connection pillars with the substrate exposed by the chip.

### BRIEF DESCRIPTION OF THE DRAWINGS

FIGS. 1-6 are schematic diagrams of structures corresponding to various steps in an embodiment of the package method of the present disclosure.

FIG. 7 is a flow chart of a package method in an embodiment of the present disclosure.

### DETAILED DESCRIPTIONS

As can be seen from the background technology, at present, with the increasing integration requirements of active electronic components in the package structure, the demand for corresponding passive components that are matched with active components has increased significantly, and there is a need for more space to place these passive components, and there is a link between the cost of the package structure on the one hand and the number of passive components and the occupied space on the other hand; how to effectively reduce the cost and volume of the package structure has become an urgent problem that package structure and method need to solve.

As the demand for passive devices increases, they take up more and more area and space in the package structure, and there is a link between the cost of the package structure on the one hand and the number of passive devices and the occupied space on the other hand. Therefore, how to effectively reduce the cost and volume of the package structure has become an urgent problem that needs to be solved for package structures and methods.

It is a problem to be solved by the embodiments of the present disclosure to provide a package structure and a package method, which improve the integration degree of the package structure while reducing costs.

In order to solve the technical problem, in the package structure provided by the embodiments of the present disclosure, a chip is located on the substrate, a plurality of spaced-apart connection pillars are located on the substrate exposed by the chip, and the two ends of the extension direction of the connection pillars are a first end and a second end, respectively, and the first end is connected with the substrate, the base board is located above the substrate, the base board is formed with passive components on the side facing the chip, and the passive components are connected with the second end of the plurality of connection pillars. In the embodiment of the present disclosure, the base board of the package structure is located above the substrate, the passive components and the chip are disposed stacked on top of one another, the passive components are connected with the substrate through a plurality of spaced-apart connection pillars, and the connection pillars are located on the substrate exposed by the chip; compared with the case of the chip and the passive components laid flat, the area of the substrate occupied by the passive components is reduced, the volume of the package structure is reduced, the integration degree of the package structure is improved, and the cost of the package structure is reduced at the same time.

In order to make the above objectives, features and advantages of the embodiments of the present disclosure more clear and understandable, the specific embodiments of the present disclosure will be described in detail below in conjunction with the accompanying drawings.

The technical solution of the embodiments of the present disclosure has the following advantages.

In the package structure provided by the embodiments of the present disclosure, a chip is located on the substrate, a plurality of spaced-apart connection pillars are located on the substrate exposed by the chip, and the two ends of the extension direction of the connection pillars are a first end and a second end, respectively, and the first end is connected with the substrate, the base board is located above the substrate, the base board is formed, on the side facing the chip, with passive components, and the passive components are connected with the second ends of the plurality of connection pillars. In the embodiment of the present disclosure, the base board of the package structure is located above the substrate, the passive components and the chip are disposed stacked on top of one another, the passive components are connected with the substrate through a plurality of spaced-apart connection pillars, and the connection pillars are located on the substrate exposed by the chip; compared with the case of the chip and the passive components laid flat, the area of the substrate occupied by the passive components is reduced, the volume of the package structure is reduced, the integration degree of the package structure is improved, and the cost of the package structure is reduced at the same time.

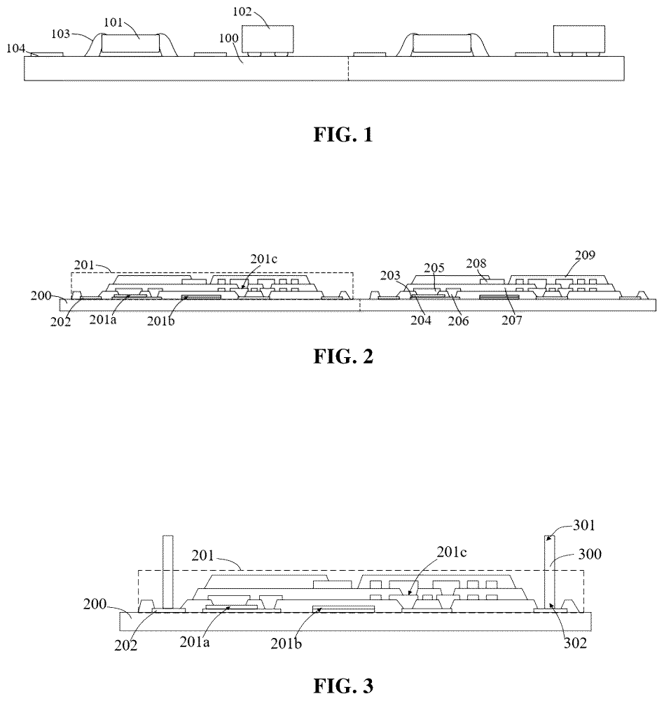

Accordingly, the present disclosure further provides a package method. FIGS. 1-6 are schematic diagrams of structures corresponding to various steps in an embodiment of the package method of the present disclosure.

Referring to FIG. 1, a substrate 100 is provided, and the substrate 100 has a chip 101 formed thereon.

In the present embodiment, the substrate 100 comprises a printed circuit board (PCB). The substrate 100 has an interconnection structure (not shown in the figures) formed in it, the interconnection structure being used to electrically connect the chip 101 with other circuit structures or devices. In other embodiments, the substrate may also comprise a silicon base board.

In the present embodiment, in the step of providing the substrate 100, on the substrate 100, a second connection end 104 is formed. The second connection end 104 is used for leading out the interconnection structure in the substrate 100 to facilitate the electrical connection in the subsequent package process.

It should also be noted that the substrate 100 comprises a plurality of chip areas (not shown in the figures), with cutting areas (not shown in the figures) being between adjacent chip areas for subsequent cutting, and the chips 101 are formed in each chip area.

In the present embodiment, the chip 101 is a radio frequency (RF) chip. In other embodiments, the chip may also be other chips.

In the present embodiment, in the step of providing the substrate 100, on the substrate 100, a functional chip 102 is further formed, which is spaced-apart from the chip 101, such as a memory chip (Memory Chip). When the package structure is working, the RF chip is responsible for handling the transmission and reception of wireless signals, while the memory chip is responsible for data access and caching, both of which are coordinated through the integrated circuits and communication interfaces in the package structure to ensure efficient processing and transmission of the data stream.

In the present embodiment, in the step of providing a substrate 100, a side of the chip 101 facing away from the substrate 100 is connected with the substrate 100 by means of lead wire 103.

Referring to FIG. 2, a base board 200 is provided, the base board 200 having a passive component 201 formed thereon.

In a subsequent package process, the base board 200 is flip-flopped onto the substrate 100 such that the chip 101 and passive component 201 are disposed stacked on top of one another.

In the present embodiment, the material of the base board 200 is silicon. In other embodiments, the material of the base board may also be germanium, silicon germanium, silicon carbide, gallium arsenide, or indium gallium, and other materials.

In the present embodiment, in the step of providing the base board 200, the passive component 201 includes a central area (not shown in the figures), and an edge area (not shown in the figures) disposed on the periphery of the central area.

The central area of the passive component 201 refers to: the area of the passive component 201 that corresponds directly to the chip 101 after the base board 200 is subsequently flip-flopped on the substrate 100, that is to say, the area where the projection of the passive component 201 on the substrate 100 overlaps with the projection of the chip 101 on the substrate 100; the edge area refers to: the area where the projection of the passive component 201 does not overlap with the projection of the chip 101 on the substrate 100 after the base board 200 is subsequently flip-flopped on the chip 101.

The passive component 201 includes a capacitor 201a, a resistor 201b, and/or an inductor 201c.

As an example, the capacitor 201a, resistor 201b and inductor 201c are located in the edge area. During the subsequent package process, in the step of connecting the first end of the connection pillars with the substrate 100 exposed by the chip 101, the projection of the capacitor 201a, resistor 201b and inductor 201c on the substrate 100 is located on the outside of the chip 101, that is to say, the capacitor 201a, resistor 201b and inductor 201c are located farther away from the chip 101, so that it is favorable to reduce the electromagnetic interference of the capacitor 201a, the resistor 201b and the inductor 201c to the chip 101 when the package structure operates.

The passive component 201 further comprises a filter device (not shown in the figures) and/or a coupler (not shown in the figures), located in the central area. The filter is used to remove unnecessary frequency components and retain useful signals, while the coupler is mainly used for transmitting and distributing signals, and disposing the filter and the coupler in the central area of the passive component 201 can optimize the electrical performance of the passive component 201.

In the present embodiment, in the step of providing the base board 200, a plurality of spaced-apart first connection ends 202 are formed in the edge area of the passive component 201. In the subsequent package process, the first connection ends 202 are connected with connection pillars, and the first connection ends 202 of the passive component 201 are led out through the connection pillars, and the first connection ends 202 are provided in the edge area of the passive component 201, which is conducive to reducing parasitic resistance and parasitic capacitance.

In the present embodiment, the first connection end 202 is a pad (welding pad), the pad being of a metallic material such as copper, tin, etc.

It is to be noted that the first connection end 202 is located in the edge area in the passive component 201 while it is also in direct contact with the surface of the base board 200. Subsequently, connection pillars are formed on the first connection end 202, and the first connection end 202 directly contacts the surface of the base board 200, facilitating the dissipation of heat from the connection pillars through the base board 200.

In the present embodiment, the passive component 201 is formed on the base board 200 using a redistribution process (RDL) and a thin film deposition process. The embodiment of the present disclosure is able to replace a large number of passive devices, such as SMD BAW/SAW filters, couplers, capacitors, resistors, and inductors in the 5G front-end RF module by intensively forming the passive components 201 on the base board 200, which can effectively reduce the area occupied by the passive devices and is conducive to improving the integration degree of the package structure, and the thinness of the package structure is realized because of the thin thickness of the film layer formed by the thin-film deposition process, and the cost of the package structure is reduced. In addition, because the thin film deposition process and the redistribution layer process can accurately control the thickness of the film layer, so that the performance of the passive devices in the passive components is stable, which is conducive to improving the performance of the package structure.

And, it is also to be noted that passive component 201 is formed using a thin film deposition process and redistribution process. The process machine can accurately control the thickness and quality of the thin film deposition process to ensure consistent performance of each component, which can reduce rework and scrap rate due to defective products, thus increasing the Units Per Hour (UPH).

Specifically, in the step of providing a base board 200, a thin film passive device, a first connection end 202, and a redistribution structure (not shown in the figures) are formed spaced-apart on the base board 200 using a thin film deposition process and a redistribution process, and the thin film passive device is connected with the first connection end 202 by the redistribution structure.

As an example, the passive device comprises: a first metal layer 203 located on the base board 200, the first metal layer 203 being formed by a patterned etching process; a thin film dielectric layer 204 located on the first metal layer 203 in partial area; a first dielectric layer 205 covering the thin film dielectric layer 204, the first metal layer 203, and the base board 200, and the first dielectric layer 205 have a first recess (not shown in the figures) exposing a portion of the thin film dielectric layer 204 and a portion of the first metal layer 203; a second metal layer 206 located on the first dielectric layer 205, and the second metal layer 206 is formed in the first recess, and the second metal layer 206 is connected with the thin film dielectric layer 204 and the first metal layer 203; a second dielectric layer 207 covering the first dielectric layer 205 and the second metal layer 206, and the second dielectric layer 207 have a second recess (not shown in the figures) exposing a portion of the second metal layer 206; a third metal layer 208, located on the second dielectric layer 207, and the third metal layer 208 is formed in the second recess, the third metal layer 208 is electrically connected with the second metal layer 206; a third dielectric layer 209 covering the second dielectric layer 207 and the third metal layer 208, the third dielectric layer 209 has a third recess (not shown in the figures) exposing a portion of the third metal layer 208, and the third recess is used to electrically connect the third metal layer 208 with an external circuit.

As an example, in a line normal to the surface of the base board 200, a stack consisting of a first metallic layer 203, a thin film dielectric layer 204, and a second metallic layer 206, serves as the capacitor 201a, specifically a film capacitor (Film capacitor).

As an example, in a line normal to the surface of the base board 200, the resistor 201b comprises a high resistivity thin film dielectric layer 204, specifically a film resistor (Film Resistor).

As an example, in a line normal to the surface of the base board 200, the second metal layer 206 and the third metal layer 208 stacked on top of one another serve as an inductor 201c, specifically a spiral inductor (Spiral Inductor).

In the present embodiment, in the step of providing a base board 200, the base board 200 comprises a plurality of passive areas, each of the passive areas having the passive component 201 formed thereon. The package method further comprises, after providing the base board 200 and before forming the connection pillars on the passive component 201, cutting the base board 200 along the boundaries of the passive areas to separate the respective the passive areas.

Cutting of the base board 200 along the boundaries of the passive area is to make it ready for the subsequent formation of a connection pillar 300 on the passive component.

Referring to FIG. 3, a plurality of spaced-apart connection pillars 300 are formed on the passive component 201, the two ends of the connection pillars 300 in the direction of extension are a first end 301 and a second end 302, respectively, and the second end 302 of the connection pillars 300 is connected with the passive component 201.

A connection pillar 300 is connected with the passive component 201 for connecting the passive component 201 with an external circuit.

In the present embodiment, the material of the connection pillar 300 is copper. In other embodiments, the material of the connection pillars may also be a metallic material such as aluminum, tin, silver, etc.

Specifically, in the step of forming a plurality of spaced-apart connection pillars 300 on the passive component 201, a second end 302 of the connection pillar 300 is connected with the first connection end 202.

It is also to be noted that in the step of forming a plurality of spaced-apart connection pillars 300 on the passive component 201, the connection pillars 300 are formed on the segmented base board 200.

In the present embodiment, the second end 302 of the connection pillar 300 protrudes from the surface of the passive component 201 facing away from the base board 200, and this configuration advantageously enables, in the subsequent package process, the second end 302 to be smoothly connected with the substrate 100.

In the present embodiment, surface-mount technology (SMT) is used to form a plurality of spaced-apart connection pillars 300 on the passive component 201. Surface-mount technology can form more components on a limited area of the passive component 201, which helps to improve the integration of the package structure; furthermore, the second end 302 of the connection pillars 300 and the first connection end 202 are direct metal connections, which is more conducive to thermal conduction.

In other embodiments, a plurality of spaced-apart connection pillars may also be formed on the passive component using a metal bonding process.

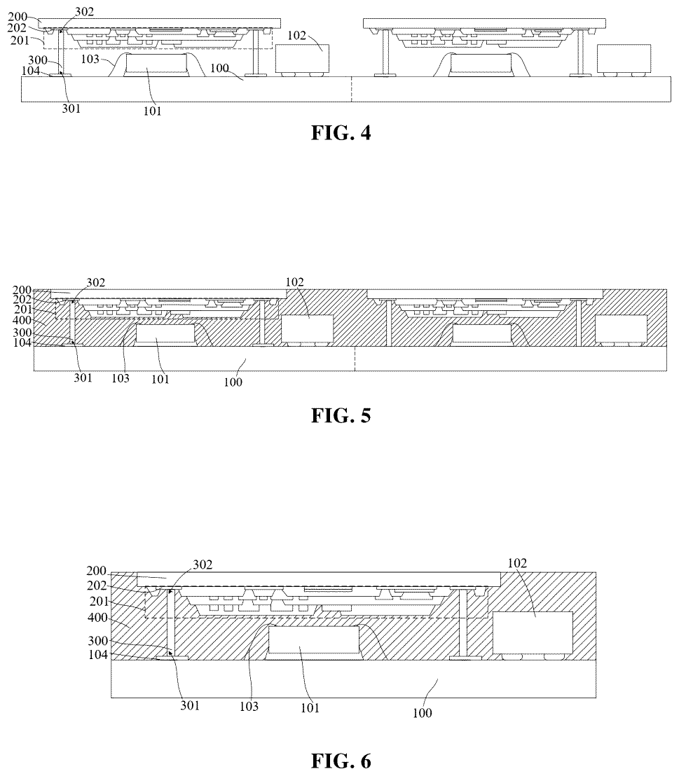

Referring to FIG. 4, the surface of the base board 200 having the passive component 201 is oriented toward the chip 101 such that the first end 301 of the connection pillars 300 is connected with the substrate 100 exposed by the chip 101, so that the base board 200 is mounted in a flip-flop manner on the substrate 100.

In the package method of the embodiments of the present disclosure, after connecting the first end 301 of the connection pillar 300 with the substrate 100 exposed by the chip 101, the base board 200 is located above the substrate 100, the passive component 201 and the chip 101 are disposed stacked on top of one another, and the passive component 201 is connected with the substrate 100 by a plurality of spaced-apart connection pillars 300, and the connection pillars 300 are located on the substrate 100 exposed by the chip 101; compared with the case where the chip 101 and the passive component 201 are disposed in a flat arrangement, the area of the substrate 100 occupied by the passive component 201 is reduced, and the volume of the package structure is reduced, and the integration degree of the package structure is improved while the cost of the package structure is reduced.

In the present embodiment, in the step of connecting the first end 301 of the connection pillars 300 with the substrate 100 exposed by the chip 101, the chip 101 is spaced-apart from the passive component 201 in the direction normal to the surface of the substrate 100, which can avoid unnecessary electrical connection between the chip 101 and the passive component 201.

Specifically, in the step of connecting the first end 301 of the connection pillar 300 with the substrate 100 exposed by the chip 101, in the direction normal to the surface of the substrate 100, the distance between the chip 101 and the passive component 201 is one-fourth to one-third of the thickness of the chip 101. If the distance between the chip 101 and the passive component 201 is too large in the direction normal to the surface of the substrate 100, then it is likely to result in the volume of the ultimately formed package structure being too large, which is not conducive to improving the integration degree of the package structure, and it is likely to generate a gap between the passive component 201 and the chip 101 in the subsequent process of forming the plastic sealing layer; because the surface of the chip 101 facing away from the substrate 100 is connected with the substrate 100 by means of the lead wire 103, if the distance between the chip 101 and the passive component 201 is too small in the direction normal to the surface of the substrate 100, it tends to cause a situation that the passive component 201 is electrically connected with the lead wire 103, resulting in poor performance of the package structure.

In the present embodiment, in the step of connecting the first end 301 of the connection pillar 300 with the substrate 100 exposed by the chip 101, the projection of the passive component 201 on the substrate 100 covers the projection of the chip 101 on the substrate 100, that is to say, the volume of the passive component 201 is larger, and accordingly more passive devices are integrated, and compared with the case of the passive component 201 in which the devices are arranged dispersed, it is possible to reduce the volume of the package structure, reduce the cost of the package structure, and improve the degree of integration.

In the present embodiment, in the step of connecting the first end 301 of the connection pillars 300 with the substrate 100 exposed by the chip 101, the central area corresponds to the chip 101, and the projections of the capacitor 201a, resistor 201b, and inductor 201c on the substrate 100 do not overlap with the projection of the chip 101 on the substrate 100. That is to say, the chip 101 is farther away from the inductor 201c, resistor 201b, and capacitor 201a in the passive component 201, which is conducive to reducing the influence of the inductor 201c, resistor 201b, and capacitor 201a in the passive component 201 on the chip 101 when the package structure is in operation.

In the present embodiment, surface mount technology is used to connect the first end 301 of the connection pillars 300 with the substrate 100 exposed by the chip 101.

Specifically, the step of connecting the first end 301 of the connection pillars 300 with the substrate 100 exposed by the chip 101 comprises: forming a solder on the second connection end 104; connecting the first end 301 of the connection pillars 300 with the solder on the second connection end 104; and reflowing the solder after connecting the first end 301 with the solder on the second connection end 104. Reflowing the solder is used to improve the bonding strength between the first end 301 of the connection pillars 300 and the substrate 100.

In the present embodiment, the solder is solder paste.

In other embodiments, a metal bonding process may also be used to connect the first end of the connection pillars with the substrate exposed by the chip.

It is also to be noted that in the step of connecting the first end 301 of the connection pillars 300 with the substrate 100 exposed by the chip 101, the connection pillars 300 are connected with an interconnection structure in the substrate 100. Specifically, the first end 301 is connected with the second connection end 104, achieving the connection between the connection pillars 300 and the interconnection structure.

Referring to FIG. 5, the method for forming a package structure further comprises forming a molding layer 400 on the substrate 100, the molding layer 400 being filled between the chip 101 and the passive component 201.

The molding layer 400 is used to package the substrate 100, the chip 101, and the passive component 201 together, providing good protection for the substrate 100, the chip 101, and the passive component 201.

In the present embodiment, the material of the molding layer 400 comprises Epoxy Molding Compound (EMC).

In the present embodiment, the molding layer 400 is formed on the substrate 100 using a transfer molding process (Transfer Molding). The transfer molding process can accurately control the amount of molding compound used, reduce material waste, and provide uniform material distribution, and ensure that there are no defects, such as air bubbles in the molding layer, so as to improve the reliability of the package structure.

It is to be noted that the surface of the base board 200 facing away from the chip 101 exposes the molding layer 400. The side of the base board 200 facing away from the substrate 100 exposes the molding layer 400, which facilitates the dissipation of heat from the package structure.

In the present embodiment, the step of forming a molding layer 400 comprises forming a molding material layer covering the substrate 100, the chip 101, the passive component 201, and the base board 200; flattening the molding material layer with the top of the base board 200 as a flattening stopping position, and the remaining layer of the molding material layer serves as the molding layer 400.

It is also to be noted that when the package structure is in operation, the first end 301 of the connection pillar 300 is connected with the substrate 100, and the second end 302 of the connection pillar 300 is connected with the passive component 201, and the connection pillar 300 is used to transfer the heat from the substrate 100 to the passive component 201 and to dissipate the heat outwardly through the base board 200.

Referring to FIG. 6, the method for forming the package structure further comprises forming the molding layer 400, cutting the molding layer 400 and the substrate 100.

The embodiment of the present disclosure cuts the cutting area between adjacent chip areas to form a plurality of separate package structures.

Referring to FIG. 6 in conjunction with FIG. 2, embodiments of the present disclosure also provide a package structure.

The package structure comprises a substrate 100; a chip 101 located on the substrate 100; a plurality of spaced-apart connection pillars 300 located on the substrate 100 exposed by the chip 101, the two ends of the extension direction of the connection pillars 300 are a first end 301 and a second end 302, respectively, the first end 301 being connected with the substrate 100; a base board 200 disposed on the substrate 100, the base board 200 having a passive component 201 formed on a surface of the base board 200 facing the chip 101, the passive component 201 being connected with a plurality of the second ends 302 of the connection pillars 300.

The base board 200 of the package structure in the embodiment of the present disclosure is located above the substrate 100, the passive component 201 and the chip 101 are disposed stacked on top of one another, and the passive component 201 is connected with the substrate 100 through a plurality of spaced-apart connection pillars 300, and the connection pillars 300 are located on the substrate 100 exposed by the chip 101; compared with the case where the chip 101 and the passive component 201 are laid flat, the area occupied by the passive component 201 on the substrate 100 is reduced, the volume of the package structure is reduced, and the integration degree of the package structure is improved while the cost of the package structure is reduced.

In the present embodiment, the substrate 100 comprises a printed circuit board, with an interconnection structure (not shown in the figures) formed in the substrate 100, and the interconnection structure is used to electrically connect the chip 101 with other circuit structures or devices. In other embodiments, the substrate may also comprise a silicon base board.

In the present embodiment, a second connection end 104 is formed on the substrate 100. The second connection end 104 is used to lead out the interconnection structure in the substrate 100.

In the present embodiment, the chip 101 is an RF chip. In other embodiments, the chip may also be other chips.

In the present embodiment, the substrate 100 is also formed with a functional chip 102, such as a memory chip, spaced-apart from the chip 101. When the package structure is in operation, the RF chip is responsible for handling the transmission and reception of wireless signals, while the memory chip is responsible for data access and caching, both of which are coordinated through the integrated circuits and communication interfaces in the package structure to ensure efficient processing and transmission of the data stream.

The package structure further comprises a lead wire 103 for connecting a surface of the chip 101 facing away from the substrate 100 with the substrate 100. The lead wire 103 is used to electrically connect the surface of the chip 101 facing away from the substrate 100 with the substrate 100.

In the present embodiment, the material of the base board 200 is silicon. In other embodiments, the material of the base board may also be germanium, silicon germanium, silicon carbide, gallium arsenide, indium gallium, or other materials.

In the present embodiment, in the direction normal to the surface of the substrate 100, the area in the passive component 201 that corresponds directly to the chip 101 is the central area, and the remaining area in the passive component 201 is the edge area.

The projection of the central area of the passive component 201 on the substrate 100 overlaps the projection of the chip 101 on the substrate 100, and the edge area refers to an area where the projection of the passive component 201 on the substrate 100 does not overlap the projection of the chip 101 on the substrate 100.

The passive component 201 comprises a capacitor 201a, a resistor 201b, and/or an inductor 201c.

As an example, the capacitor 201a, resistor 201b and inductor 201c are located in the edge area. That is to say, the capacitor 201a, resistor 201b and inductor 201c are farther away from the chip 101, so that when the package structure is working, it is beneficial to reduce the electromagnetic interference of the capacitor 201a, resistor 201b, and inductor 201c on the chip 101.

The passive component 201 further comprises a filter device (not shown in the figures) and/or a coupler (not shown in the figures), located in the central area. The filter is used to remove unnecessary frequency components and retain useful signals, while the coupler is mainly used for transmitting and distributing signals, and disposing the filter and the coupler in the central area of the passive component 201 can optimize the electrical performance of the passive component 201.

In the present embodiment, the passive component 201 further comprises a plurality of spaced-apart first connection ends 202 provided in the edge area, the first connection ends 202 being connected with the second ends 302 of the connection pillars 300, the first connection ends 202 of the passive component 201 being led out through the connection pillars 300.

The first connection end 202 is provided in the edge area of the passive component 201, which facilitates the reduction of parasitic resistance and parasitic capacitance.

In the present embodiment, the first connection end 202 is a pad (welding pad), the pad being of a metallic material such as copper, tin, etc.

It is to be noted that the first connection end 202 is located in the edge area in the passive component 201 and meanwhile is also in direct contact with the surface of the base board 200. The direct contact of the first connection end 202 with the surface of the base board 200 facilitates the dissipation of heat from the connection pillar 300 through the base board 200.

The connection pillars 300 are connected with the passive component 201, for connecting the passive component 201 with an external circuit.

In the present embodiment, the material of the connection pillar 300 is copper. In other embodiments, the material of the connection pillars may also be a metallic material such as aluminum, tin, silver, etc.

Specifically, a second end 302 of the connection pillars 300 is connected with the first connection end 202.

In the present embodiment, the second end 302 of the connection pillar 300 protrudes on the surface of the passive component 201, facing away from the base board 200. The chip 101 is spaced-apart from the passive component 201 in a direction normal to the surface of the substrate 100.

In the present embodiment, the passive component 201 is formed on the base board 200 using a redistribution process (RDL) and a thin film deposition process. The embodiment of the present disclosure is able to replace a large number of passive devices, such as SMD BAW/SAW filters, couplers, capacitors, resistors, and inductors in the 5G front-end RF module by intensively forming the passive component 201 on the base board 200, which can effectively reduce the area occupied by the passive device and is conducive to improving the integration degree of the package structure, and the thinness of the package structure is realized because of the thin thickness of the film layer formed by the thin-film deposition process, and the cost of the package structure is reduced. In addition, because the thin film deposition process and the redistribution layer process can accurately control the thickness of the film layer, so that the performance of the passive devices in the passive components is stable, which is conducive to improving the performance of the package structure.

And it is also to be noted that passive component 201 is formed using a redistribution process and a thin film deposition process. The process machine can accurately control the thickness and quality of the thin film deposition process to ensure consistent performance of each component, which can reduce rework and scrap rate due to defective products, thus increasing the Units Per Hour (UPH).

Specifically, the passive component comprises a thin film passive device; a plurality of spaced-apart first connection ends 202 spaced apart from the thin film passive device; and a redistribution structure for connecting the first connection ends 202 with the thin film passive device, the thin film passive device, the first connection ends 202, and the redistribution structure being formed using a thin film deposition process and a redistribution process.

As an example, as shown in FIG. 2, the passive device comprises: a first metal layer 203 located on the base board 200, the first metal layer 203 being processed using patterned etching; a thin film dielectric layer 204 located on the first metal layer 203 in partial area; a first dielectric layer 205 covering the thin film dielectric layer 204, the first metal layer 203, and the base board 200, and the first dielectric layer 205 having a first recess (not shown in the figures) exposing a portion of the thin film dielectric layer 204 and a portion of the first metal layer 203; a second metal layer 206 located on the first dielectric layer 205, the second metal layer 206 being formed in the first recess, the second metal layer 206 being connected with the thin film dielectric layer 204 and the first metal layer 203; a second dielectric layer 207 covering the first dielectric layer 205 and the second metal layer 206, the second dielectric layer 207 having a second recess (not shown in the figures) exposing a portion of the second metal layer 206; a third metal layer 208, located on the second dielectric layer 207, the third metal layer 208 being formed in the second recess, the third metal layer 208 being electrically connected with the second metal layer 206; a third dielectric layer 209 covering the second dielectric layer 207 and the third metal layer 208, the third dielectric layer 209 having a third recess (not shown in the figures) exposing a portion of the third metal layer 208, the third recess being used to electrically connect the third metal layer 208 with an external circuit.

As an example, in a line normal to the surface of the base board 200, a stack consisting of a first metallic layer 203, a thin film dielectric layer 204, and a second metallic layer 206 serves as the capacitor 201a, specifically a film capacitor (Film capacitor).

As an example, in a line normal to the surface of the base board 200, a stack consisting of a first metallic layer 203 and a thin film dielectric layer 204 serves as the resistor 201b, specifically a thin film resistor (Film Resistor).

As an example, in a line normal to the surface of the base board 200, the second metal layer 206 and the third metal layer 208 stacked on top of one another serve as an inductor 201c, specifically a spiral inductor (Spiral Inductor).

In the present embodiment, in a direction normal to the substrate 100, the chip 101 is spaced-apart from the passive component 201, which can avoid unnecessary electrical connection between the chip 101 and the passive component 201.

Specifically, in the direction normal to the surface of the substrate 100, the distance between the chip 101 and the passive component 201 is one-fourth to one-third of the thickness of the chip 101. If the distance between the chip 101 and the passive component 201 is too large in the direction normal to the surface of the substrate 100, it will result in the volume of the package structure being too large, which is not conducive to improving the integration degree of the package structure, and it is likely to generate a gap between the passive component 201 and the chip 101 in the process of forming the plastic sealing layer; because the surface of the chip 101 facing away from the substrate 100 is connected with the substrate 100 by means of the lead wire 103, if the distance between the chip 101 and the passive component 201 is too small in the direction normal to the surface of the substrate 100, it tends to cause a situation that the passive component 201 is electrically connected with the lead wire 103, resulting in poor performance of the package structure.

In the present embodiment, the projection of the passive component 201 on the substrate 100 covers the projection of the chip 101 on the substrate 100. That is to say, the volume of the passive component 201 is larger, and accordingly more passive devices are integrated, and compared to the case of the passive component 201 in which the devices are dispersed and set up, it is possible to reduce the volume of the package structure, reduce the cost of the package structure, and improve the degree of integration.

In the present embodiment, the projection of the capacitor 201a, resistor 201b, and inductor 201c on the substrate 100 does not overlap with the projection of the chip 101 on the substrate 100. That is to say, the chip is farther away from the inductor 201c, resistor 201b, and capacitor 201a in the passive component 201, which is conducive to reducing the influence of the inductor 201c, resistor 201b, and capacitor 201a in the passive component 201 on the chip 101 during the operation of the package structure.

It is also to be noted that when connecting the first end 301 of the connection pillars 300 with the substrate 100 exposed by the chip 101, the connection pillars 300 are connected with the interconnection structure in the substrate 100. Specifically, the first end 301 is connected with the second connection end 104, achieving the connection of the connection pillar 300 and the interconnection structure.

The package structure further comprises a molding layer 400 located on the substrate 100, the molding layer 400 being filled between the chip 101 and passive component 201, and the surface of the base board 200 facing away from the chip 101 exposes the molding layer 400.

The molding layer 400 is used to package the substrate 100, the chip 101, and the passive component 201 together, providing good protection for the substrate 100, the chip 101, and the passive component 201.

In the present embodiment, the material of the molding layer 400 comprises Epoxy Molding Compound (EMC).

It is to be noted that the surface of the base board 200 facing away from the chip 101 exposes the molding layer 400.

The side of the base board 200 facing away from the substrate 100 exposes the molding layer 400, which facilitates heat dissipation of the package structure.

It is also to be noted that when the package structure is in operation, the first end 301 of the connection pillar 300 is connected with the substrate 100, and the second end 302 of the connection pillar 300 is connected with the passive component 201, and the connection pillar 300 is used to transfer the heat of the substrate 100 to the passive component 201 and to dissipate the heat outwardly through the base board 200.

The package structure may be formed by the package method described in the aforementioned embodiments, or may be formed by other package methods. For the specific description of the package structure described in the present embodiment, reference may be made to the corresponding description in the aforementioned embodiments, and the present embodiment will not be repeated herein.

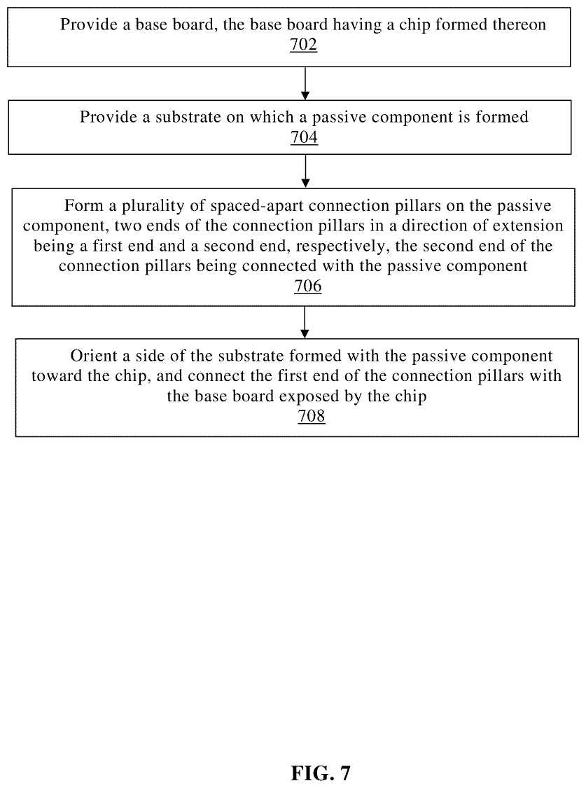

FIG. 7 is a flow chart of a package method in an embodiment of the present disclosure. At operation 702, a substrate 100 having a chip 101 formed thereon is provided. At operation 704, a base board 200 on which a passive component 201 is formed is provided. At operation 706, a plurality of spaced-apart connection pillars 300 are formed on the passive component 201. Two ends of the connection pillars 300 in a direction of extension are a first end and a second end, respectively. The second end of the connection pillars 300 is connected with the passive component 201. At operation 708, a side of the base board 200 formed with the passive component 201 is oriented toward the chip 101, and the first end of the connection pillars 300 is connected with the substrate 100 exposed by the chip 101.

Although the present disclosure is disclosed as above, the present disclosure is not limited thereto. Any person skilled in the art may make various changes and modifications without departing from the spirit and scope of the present disclosure, and therefore the scope of protection of the present disclosure shall be defined by the scope limited by the claims.

What is claimed is:

1. A package structure, comprising:
a substrate;
a chip disposed on the substrate;
a plurality of spaced-apart connection pillars disposed on the substrate exposed by the chip, and two ends of an extension direction of the connection pillars are a first end and a second end, respectively, the first end being connected with the substrate; and
a base board located above the substrate, and a passive component is formed on a side of the base board facing the chip, the passive component being connected with the second end of the plurality of the connection pillars.

2. The package structure according to claim 1, wherein the passive component comprises:
thin film passive devices;
a plurality of spaced-apart first connection ends disposed spaced from the thin film passive devices; and
a redistribution structure for connecting the first connection end with the thin film passive devices, wherein the thin film passive devices, the first connection end, and the redistribution structure are formed using a thin film deposition process and a redistribution process.

3. The package structure according to claim 2, wherein
in a direction normal to a surface of the substrate, an area of the passive component corresponding directly to the chip is a central area, and the remaining area of the passive component is an edge area; and
the plurality of spaced-apart first connection ends are provided in the edge area, the first connection ends being connected with second ends of the connection pillars.

4. The package structure according to claim 1, wherein
in a direction normal to a surface of the substrate, an area of the passive component corresponding directly to the chip is a central area, and the remaining area of the passive component is an edge area; and
the passive component comprises at least one of a capacitor, a resistor, or an inductor, located in the edge area.

5. The package structure according to claim 4, wherein the passive component further comprises at least one of a filter device or a coupler, located in the central area.

6. The package structure according to claim 1, wherein the package structure further comprises:
a molding layer located on the substrate, the molding layer being filled between the chip and passive component, and a surface of the base board facing away from the chip exposes the molding layer.

7. The package structure according to claim 1, wherein a projection of the passive component on the substrate covers a projection of the chip on the substrate.

8. The package structure according to claim 1, wherein the chip is disposed spaced from the passive component in a direction normal to a surface of the substrate and a distance between the chip and the passive component is one quarter to one third of a thickness of the chip.

9. The package structure according to claim 1, wherein the package structure further comprises:
lead wires which connect a surface of the chip facing away from the substrate with the substrate.

10. A package method, comprising:
providing a substrate, the substrate having a chip formed thereon;
providing a base board on which a passive component is formed;
forming a plurality of spaced-apart connection pillars on the passive component, two ends of the connection pillars in a direction of extension being a first end and a second end, respectively, the second end of the connection pillars being connected with the passive component; and
orienting a side of the base board formed with the passive component toward the chip, and connecting the first end of the connection pillars with the substrate exposed by the chip.

11. The package method according to claim 10, wherein in providing a base board, a thin film deposition process and a redistribution process are used on the base board to form spaced-apart thin film passive devices, a first connection end, and a redistribution structure, the thin film passive devices being connected with the first connection end by the redistribution structure.

12. The package method according to claim 10, wherein
in providing a base board, the passive component comprises a central area and an edge area located at a periphery of the central area, and in the edge area of the passive component, a plurality of spaced-apart first connection ends are formed;
in forming a plurality of spaced-apart connection pillars on the passive component, a second end of the connection pillar is connected with the first connection end; and
in connecting the first end of the connection pillars with a substrate exposed by the chip, a projection of the first connection end on the substrate does not overlap with a projection of the chip on the substrate.

13. The package method according to claim 10, wherein
in providing a base board, the passive component comprises a central area and an edge area located at a periphery of the central area, and in the edge area of the passive component, at least one of a capacitor, a resistor, or an inductor are formed; and
in connecting the first end of the connection pillars with a substrate exposed by the chip, a projection of the at least one of the capacitor, resistor or inductor on the substrate does not overlap with a projection of the chip on the substrate.

14. The package method according to claim 10, wherein connecting the first end of the connection pillars with a substrate exposed by the chip, a projection of the passive component on the substrate covers a projection of the chip on the substrate.

15. The package method according to claim 10, further comprising:
forming a molding layer on the substrate, the molding layer being filled between the chip and the passive component, and the molding layer being exposed on a side of the base board facing away from the chip.

16. The package method according to claim 10, wherein in connecting the first end of the connection pillars with a substrate exposed by the chip, the chip is spaced-apart from the passive component in a direction normal to a surface of the base board, and a distance is one-fourth to one-third of a thickness of the chip.

17. The package method according to claim 10, wherein
providing a substrate, a second connection end is formed on the substrate; and
connecting a first end of the connection pillars with a substrate exposed by the chip comprises:
forming a solder on the second connection end;
connecting the first end of the connection pillars with the solder on the second connection end; and
reflowing the solder after connecting the first end with the solder on the second connection end.

18. The package method according to claim 10, wherein
a plurality of spaced-apart connection pillars are formed on the passive component using surface mounting techniques; or
a plurality of spaced-apart connection pillars are formed on the passive component using a metal bonding process.

19. The package method according to claim 10, wherein
in providing a base board, the base board comprises a plurality of passive areas, and the passive component is formed on each of the passive areas;
the package method further comprises after providing the base board and before forming a plurality of spaced-apart connection pillars on the passive component, cutting the base board along boundaries of the passive areas to separate individual passive areas; and
in forming a plurality of connection pillars spaced-apart on the passive component, the connection pillars are formed on the base board.

20. The package method according to claim 10, wherein in providing a substrate, a surface of the chip facing away from the substrate is connected with the substrate by a lead wire.
